(19) United States
(12) Patent Application Publication
(10) Pub. No.: US 2020/0251516 A1
(43) Pub. Date: Aug. 6, 2020

(54) SEMICONDUCTOR DEVICE, SOLID-STATE IMAGE SENSOR, MANUFACTURING METHOD, AND ELECTRONIC DEVICE

(71) Applicant: SONY SEMICONDUCTOR SOLUTIONS CORPORATION, KANAGAWA (JP)

(72) Inventor: TOSHIHIRO MIURA, KANAGAWA (JP)

(21) Appl. No.: 16/757,162

(22) PCT Filed: Oct. 12, 2018
(86) PCT No.: PCT/JP2018/038060

§ 371 Date: Apr. 17, 2020

(30) Foreign Application Priority Data
Oct. 26, 2017 (JP) 2017-206754

(51) Int. Cl. H01L 27/146; H01L 23/544

(52) U.S. Cl. CPC H01L 27/14632; H01L 2223/5446; H01L 27/14687; H01L 23/544

(57) ABSTRACT

The present disclosure relates to a semiconductor device, a solid-state image sensor, a manufacturing method, and an electronic device that can promote stabilization of device characteristics. The solid-state image sensor is provided with a pixel region that is a region where a pixel is formed on a semiconductor substrate, and a peripheral region that is a region where a pixel is not formed on the semiconductor substrate. Then, a stopper layer is formed in the semiconductor substrate at a predetermined depth in the peripheral region with a material different from that of the semiconductor substrate, and a dug portion is formed by digging the pixel region and the peripheral region of the semiconductor substrate to a depth corresponding to the stopper layer. At this time, the end point of the processing time for digging the dug portion is determined by utilizing the detection of a compound containing the material of the stopper layer. The present technology can be applied to a CMOS image sensor, for example.

### TECHNICAL FIELD

The present disclosure relates to a semiconductor device, a solid-state image sensor, a manufacturing method, and an electronic device, and particularly to a semiconductor device, a solid-state image sensor, a manufacturing method, and an electronic device that can stabilize device characteristics.

### BACKGROUND ART

Conventionally, a semiconductor substrate on which a dug portion having a predetermined depth is formed by etching is used for a semiconductor device such as a solid-state image sensor.

Generally, when processing such a dug portion, interference wave etch pit density (EPD) is used to control the processing depth of the dug portion. For example, the interference wave EPD is a method of irradiating a laser beam from above, monitoring the etching depth from a phase difference between the reflected wave of a region where a mask such as photoresist is disposed and not etched and the reflected wave of an etched region, and detecting an end point at a desired etching depth. For example, the interference wave EPD is a method that is effective under conditions where the processing depth is relatively shallow, 1 μm or less, and the aperture ratio is about 30% or more, such as shallow trench isolation (STI) processing.

On the other hand, in a case where the aperture ratio is less than 20%, for example, the reflected wave in the etched region cannot be detected sufficiently, and it is very difficult to monitor the etching depth by the interference wave EPD. Specifically, in a case of processing a hole pattern in a semiconductor substrate, since the aperture ratio is about 1%, it has not been considered realistic to monitor the etching depth using the interference wave EPD.

For example, Patent Document 1 discloses a manufacturing method of a semiconductor device in which, when forming a trench in a semiconductor substrate by plasma etching processing, the plasma etching processing is performed while detecting a plasma impedance.

### CITATION LIST

### Patent Document

Patent Document 1: Japanese Patent Application Laid-Open No. 2007-287855

### SUMMARY OF THE INVENTION

### Problems to be Solved by the Invention

As described above, since it is difficult to monitor the processing depth when forming a dug portion in a silicon substrate, it is difficult to control the processing depth to be constant, and there have been cases where the depth of the dug portion varies among devices. Hence, the characteristic varies depending on the device, and it has been required to stabilize device characteristics.

The present disclosure has been made in view of such circumstances, and aims to stabilize device characteristics.

### Solutions to Problems

A semiconductor device of one aspect of the present disclosure includes: an effective region that is a region where a semiconductor element required to function effectively is formed on a semiconductor substrate; an ineffective region that is a region in the semiconductor substrate where the semiconductor element is not formed; a stopper layer that is formed in the semiconductor substrate at a predetermined depth in the ineffective region and includes a material different from the semiconductor substrate; and a dug portion that is formed by digging the effective region and the ineffective region of the semiconductor substrate to a depth corresponding to the stopper layer.

A solid-state image sensor of one aspect of the present disclosure includes: a pixel region that is a region where a pixel required to function effectively is formed on a semiconductor substrate; a peripheral region that is a region in the semiconductor substrate where the pixel is not formed; a stopper layer that is formed in the semiconductor substrate at a predetermined depth in the peripheral region and includes a material different from the semiconductor substrate; and a dug portion that is formed by digging the pixel region and the peripheral region of the semiconductor substrate to a depth corresponding to the stopper layer.

The manufacturing method of one aspect of the present disclosure is a manufacturing method of a semiconductor device that includes: an effective region that is a region where a semiconductor element required to function effectively is formed on a semiconductor substrate; an ineffective region that is a region in the semiconductor substrate where the semiconductor element is not formed; a stopper layer that is formed in the semiconductor substrate at a predetermined depth in the ineffective region and includes a material different from the semiconductor substrate; and a dug portion that is formed by digging the effective region and the ineffective region of the semiconductor substrate to a depth corresponding to the stopper layer, the method including forming the stopper layer on the semiconductor substrate thinner than a specified thickness, and epitaxially growing the semiconductor substrate to a specified thickness.

An electronic device of one aspect of the present disclosure includes a semiconductor device that has: an effective region that is a region where a semiconductor element required to function effectively is formed on a semiconductor substrate; an ineffective region that is a region in the semiconductor substrate where the semiconductor element is not formed; a stopper layer that is formed in the semiconductor substrate at a predetermined depth in the ineffective region and includes a material different from the semiconductor substrate; and a dug portion that is formed by digging the effective region and the ineffective region of the semiconductor substrate to a depth corresponding to the stopper layer.

In one aspect of the present disclosure, an effective region (pixel region), that is a region where a semiconductor element (pixel) required to function effectively is formed on a semiconductor substrate, and an ineffective region (peripheral region) that is a region in the semiconductor substrate where the semiconductor element (pixel) is not formed are provided. Then, a stopper layer is formed in the semiconductor substrate at a predetermined depth in the ineffective region (peripheral region) and includes a material different from the semiconductor substrate. A dug portion is formed by digging the effective region (pixel region) and the ineffective region (peripheral region) of the semiconductor substrate to a depth corresponding to the stopper layer.

### Effects of the Invention

According to an aspect of the present disclosure, device characteristics can be stabilized.

Note that the effect described herein is not necessarily limited, and may be any effect described in the present disclosure.

### BRIEF DESCRIPTION OF DRAWINGS

FIG. 1 is a perspective view showing a configuration example of a first embodiment of a solid-state image sensor to which the present technology is applied.

FIG. 2 is a diagram showing a cross-sectional configuration of a part of the solid-state image sensor.

FIG. 3 is a diagram showing a state in which a solid-state image sensor is formed on a wafer before dicing.

FIG. 4 is an enlarged view showing a region corresponding to dashed circle A shown in FIG. 3.

FIG. 5 is an enlarged view showing a region corresponding to dashed circle B shown in FIG. 3.

FIG. 6 is a diagram illustrating a first manufacturing method of a solid-state image sensor.

FIG. 7 is a diagram illustrating a second manufacturing method of a solid-state image sensor.

FIG. 8 is a diagram illustrating an example of implanting impurities into a deep region.

FIG. 9 is a cross-sectional view showing a configuration example of a second embodiment of a solid-state image sensor to which the present technology is applied.

FIG. 10 is a cross-sectional view illustrating a configuration example of a third embodiment of a solid-state image sensor to which the present technology is applied.

FIG. 11 is a diagram illustrating a manufacturing method of the solid-state image sensor shown in FIG. 10.

FIG. 12 is a block diagram showing a configuration example of an imager.

FIG. 13 is a diagram showing use examples of an image sensor.

FIG. 14 is a diagram showing one example of a schematic configuration of an endoscopic surgery system.

FIG. 15 is a block diagram showing one example of a functional configuration of a camera head and a CCU.

FIG. 16 is a block diagram showing one example of a schematic configuration of a vehicle control system.

FIG. 17 is an explanatory diagram showing one example of installation positions of an outside information detection unit and an imaging unit.

### MODE FOR CARRYING OUT THE INVENTION

Hereinafter, specific embodiments to which the present technology is applied will be described in detail with reference to the drawings.

### <First Configuration Example of Solid-State Image Sensor>

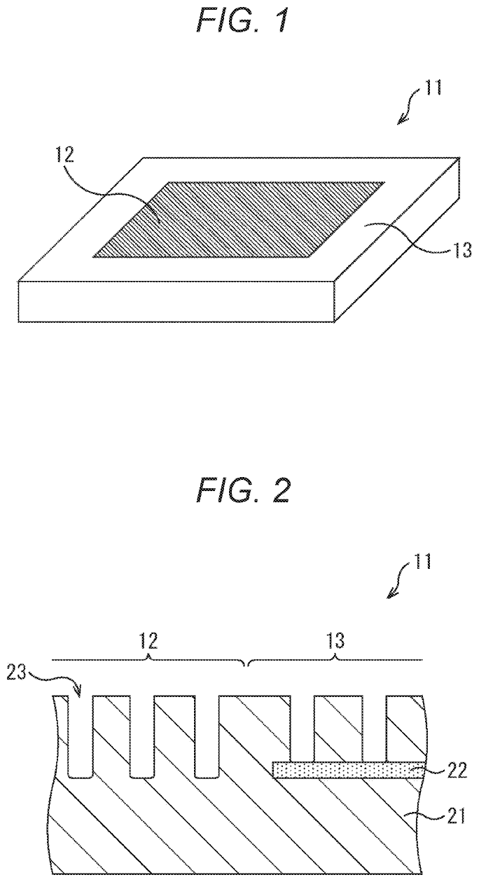

A first embodiment of a solid-state image sensor to which the present technology is applied will be described with reference to FIGS. 1 to 5.

FIG. 1 is a perspective view of a solid-state image sensor 11.

For example, the solid-state image sensor 11 is a complementary metal oxide semiconductor (CMOS) image sensor, and a pixel area 12 is provided at the center of the solid-state image sensor 11, while a region surrounding the pixel area 12 is a peripheral area 13.

The pixel area 12 is a sensor surface on which an image of a subject is formed when the solid-state image sensor 11 captures an image. In the pixel area 12, multiple pixels required to function effectively when capturing an image are formed in an array.

In the peripheral area 13, a driving circuit for driving pixels, connection pads used for connection with external devices, and the like are formed, and pixels required to function effectively when capturing an image are not formed, for example.

FIG. 2 shows a cross-sectional configuration of a part of the solid-state image sensor 11.

As shown in FIG. 2, the solid-state image sensor 11 includes a semiconductor substrate 21 including silicon or the like, and a stopper layer 22 is formed in the peripheral area 13. The stopper layer 22 is formed at a predetermined depth of the semiconductor substrate 21 using silicon nitride (SiN), for example, as the material.

Additionally, multiple dug portions 23 formed in a circular blind hole shape (non-penetrating), for example, are provided in the pixel area 12 and the peripheral area 13 by digging the surface of the solid-state image sensor 11 by etching. For example, the stopper layer 22 formed in the peripheral area 13 has a function of detecting a processing depth when performing processing for forming the multiple dug portions 23.

That is, when processing the multiple dug portions 23 on the semiconductor substrate 21, a compound generated by processing the stopper layer 22 can be detected by optical emission spectrometry (OES) using plasma emission. Alternatively, the compound can be detected by a quadrupole mass analyzer (Q-Mass), which is a kind of mass spectrometer.

Here, as the stopper layer 22, a compound of a type different from the semiconductor substrate 21 (for example, silicon) to be processed can be used. Specifically, the stopper layer 22 is formed using, as the material, a compound containing silicon such as SiN, N, SiO, SiON, and SiC, or a compound containing metal such as Al, W, and TiN, for example.

For example, when processing multiple dug portions 23, a compound containing nitrogen is generated in a case where silicon nitride (SiN) is used as the stopper layer 22, and a compound containing oxygen is generated in a case where silicon monoxide (SiO) is used as the stopper layer 22. Accordingly, generation of compounds other than these silicons can be detected by monitoring the emission of plasma.

As described above, the end point of the etching time when etching the multiple dug portions 23 can be determined by utilizing the detection of the compound generated by processing the stopper layer 22. As a result, it is possible to curb variation in the processing depth of the multiple dug portions 23 formed in the pixel area 12 among solid-state image sensors 11, and process the multiple dug portions 23 so that a constant processing depth can be achieved in each solid-state image sensor 11.

Additionally, since the solid-state image sensor 11 has a configuration in which the stopper layer 22 is selectively formed only in the peripheral area 13, it is possible to prevent the stopper layer 22 from affecting pixels formed in the pixel area 12. That is, in a configuration in which the stopper layer 22 is formed in the pixel area 12, it is assumed that performance will be degraded due to the influence of the stopper layer 22 on the pixels. However, such degradation in performance does not occur in the solid-state image sensor 11.

The solid-state image sensor 11 configured as described above can process multiple dug portions 23 so as to have a constant processing depth without causing variation among devices. Hence, device characteristics can be stabilized.

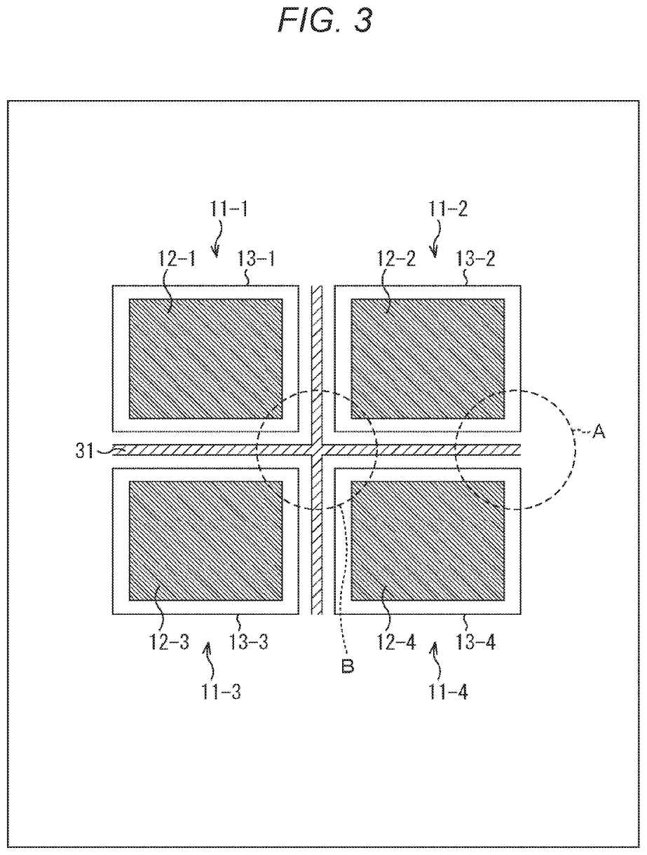

The region where the stopper layer 22 is formed will be described with reference to FIGS. 3 to 5.

FIG. 3 shows an image of four solid-state image sensors 11-1 to 11-4 formed on a wafer before dicing, as viewed from above. As shown in FIG. 3, a dicing region 31, which is a region to be removed by dicing, is provided so as to divide the solid-state image sensors 11-1 to 11-4. In a case of processing the multiple dug portions 23 in such a state of the wafer, in addition to the peripheral area 13, the stopper layer 22 may be formed in a scribe line (line between solid-state image sensors 11) including the dicing region 31.

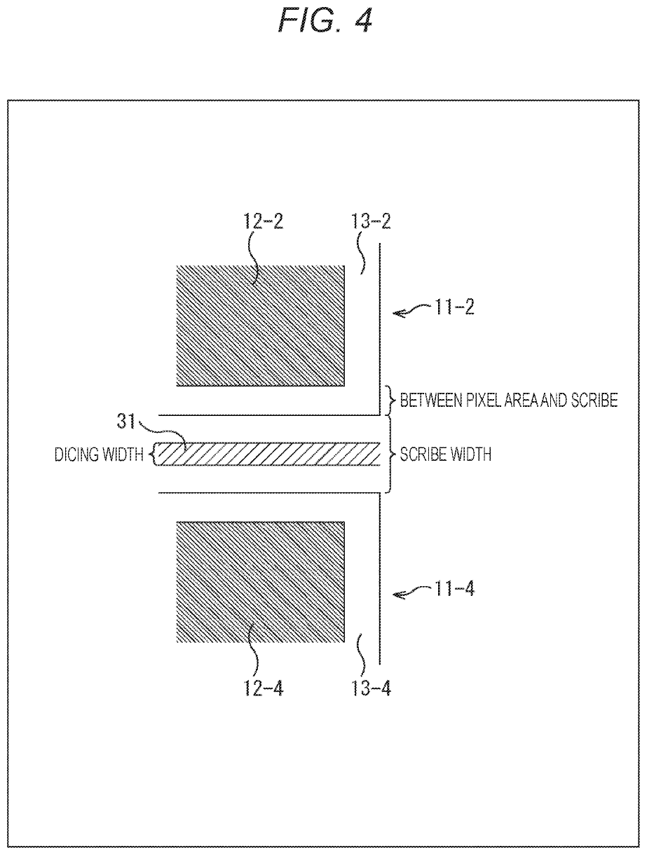

FIG. 4 shows an enlarged region corresponding to dashed circle A of FIG. 3. For example, the dicing width of the dicing region 31 is about 40 μm, and the scribe width, which is the spacing between the solid-state image sensors 11, is about 100 to 200 μm. Additionally, the spacing between the pixel area 12 and the scribe line, that is, the width of the peripheral area 13 is about 200 to 300 μm.

For example, in a configuration in which the stopper layer 22 is provided only in the dicing region 31, a hole pattern is provided in a dicing width of about 40 μm. Accordingly, in this configuration, in a case where the chip width of the solid-state image sensor 11 is 5 mm, since the dicing width is 1% or less of the whole width, the aperture ratio is 0.1% or less. Hence, it is very difficult to monitor the etching depth of the multiple dug portions 23 by the interference wave EPD described above.

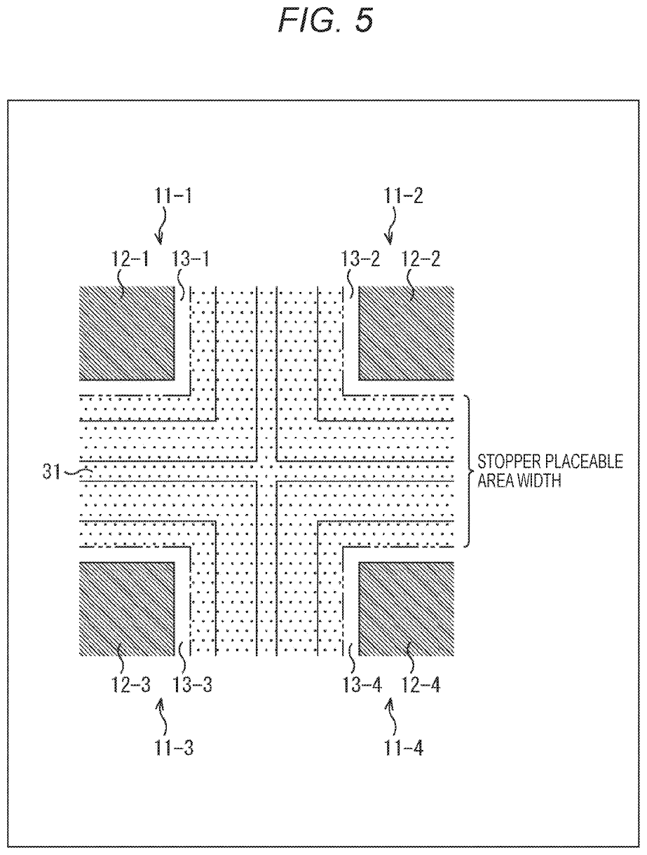

For this reason, it is preferable to provide a region where the stopper layer 22 can be provided as indicated by dotted hatching in FIG. 5, and to set the width of the region to about 500 μm. FIG. 5 shows an enlarged region corresponding to dashed circle B of FIG. 3.

As shown in FIG. 5, the region width in which the stopper layer 22 can be provided is provided wider than the scribe width including the dicing region 31, and an outer region at a certain distance from the pixel area 12 (not hatched region in FIG. 5) is provided as the region where the stopper layer 22 can be provided. Additionally, the stopper layer 22 is formed in a position avoiding a mark for alignment provided in this region, a peripheral circuit, and the like.

Additionally, the larger the aperture ratio of the dug portion 23 formed so as to open in the stopper layer 22, the larger the emission change due to the compound generated by processing the stopper layer 22. Hence, it is desirable to increase the aperture ratio of the dug portion 23 formed so as to open in the stopper layer 22. However, it is possible to detect the emission change with an aperture ratio of about 1% (of area of solid-state image sensor 11, for example), for example.

### <Manufacturing Method of Solid-State Image Sensor>

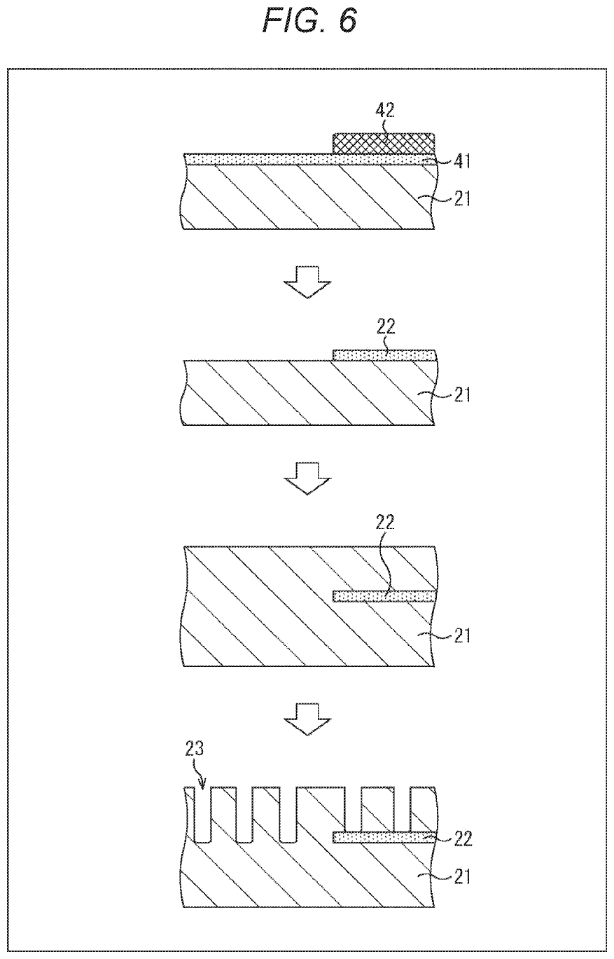

A first manufacturing method of the solid-state image sensor 11 will be described with reference to FIG. 6.

In a first step, as shown in the first row of FIG. 6, a silicon nitride used as the stopper layer 22 is formed on the semiconductor substrate 21 having a thickness smaller than a specified thickness to form an SiN film 41 on the entire surface of the semiconductor substrate 21. Then, a resist 42 is placed in accordance with the area to be the peripheral area 13.

In a second step, as shown in the second row of FIG. 6, reactive ion etching (RIE) processing is performed to remove the SiN film 41 in the pixel area 12 using the resist 42, and a damaged layer on the surface of the semiconductor substrate 21 is removed. After the stopper layer 22 is formed in this manner, the resist 42 is removed.

In a third step, as shown in the third row of FIG. 6, the semiconductor substrate 21 having a specified thickness is formed by epitaxially growing silicon.

In a fourth step, as shown in the fourth row of FIG. 6, the semiconductor substrate 21 is processed to form multiple dug portions 23 using a resist, for example. At this time, as described above, the end point of the etching time is determined using the detection of a compound generated by processing the stopper layer 22.

Additionally, the processing depth of the multiple dug portions 23 in the pixel area 12 can actually be adjusted to a desired processing depth by performing over-etching after determining the end point of the etching time using the stopper layer 22.

With the manufacturing method described above, the processing depth of the multiple dug portions 23 formed in the pixel area 12 can be controlled accurately. As a result, it is possible to manufacture the solid-state image sensor 11 so as to curb variation in the processing depth of the multiple dug portions 23 among the solid-state image sensors 11, and stabilize device characteristics.

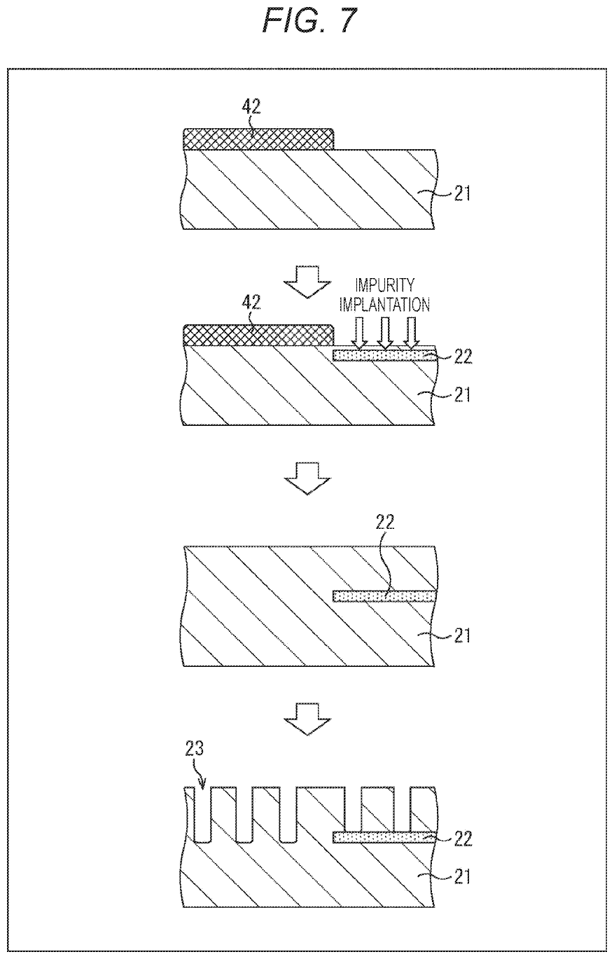

A second manufacturing method of the solid-state image sensor 11 will be described with reference to FIG. 7.

In an eleventh step, as shown in the first row of FIG. 7, the resist 42 is placed in accordance with a region to be the pixel area 12 of the semiconductor substrate 21 which is thinner than a specified thickness.

In a twelfth step, as shown in the second row of FIG. 7, using the resist 42 as a mask, a high concentration of impurities (P, B, As, N, and the like) for forming the stopper layer 22 are implanted near the surface of the semiconductor substrate 21.

In a thirteenth step, as shown in the third row of FIG. 7, the semiconductor substrate 21 having a specified thickness is formed by epitaxially growing silicon.

In a fourteenth step, as shown in the fourth row of FIG. 7, the semiconductor substrate 21 is processed to form multiple dug portions 23 using a resist. At this time, as described above, the end point of the etching time is determined using the detection of a compound generated by processing the stopper layer 22.

With the manufacturing method described above, the processing depth of the multiple dug portions 23 formed in the pixel area 12 can be controlled accurately. As a result, it is possible to manufacture the solid-state image sensor 11 so as to curb variation in the processing depth of the multiple dug portions 23 among the solid-state image sensors 11, and stabilize device characteristics.

Additionally, the method of providing the stopper layer 22 in a specific location in the semiconductor substrate 21 is not limited to a substrate using silicon, and the present invention can also be applied to a substrate using a compound such as gallium arsenide (GaAs) or gallium nitride (GaN), for example.

Here, for example, a method of providing the stopper layer 22 on a single-layer semiconductor substrate 21 without performing the step of epitaxially growing silicon (for example, third step in FIG. 6 or thirteenth step in FIG. 7) is considered.

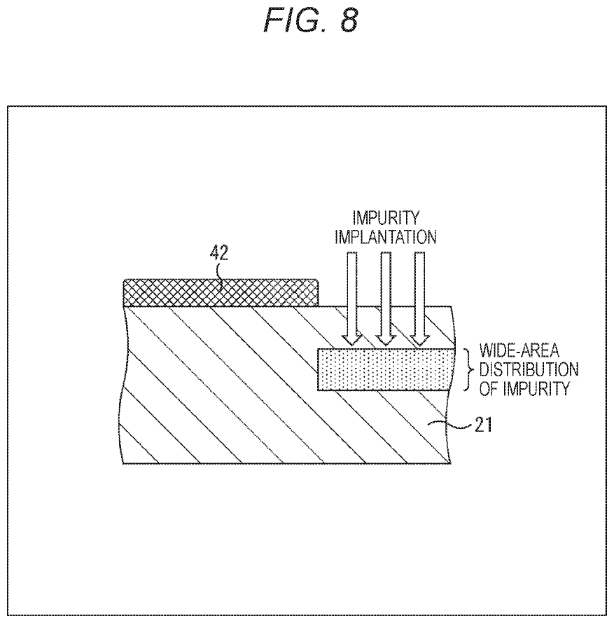

That is, as shown in FIG. 8, by implanting impurities for forming the stopper layer 22 into a deep region of the semiconductor substrate 21 having a specified thickness, it is considered that the step of epitaxially growing silicon becomes unnecessary. However, in this method, the impurities are distributed so as to spread in a wide area in the vertical direction, and it is assumed that the impurities are difficult to use for determining the end point of the etching time for obtaining a constant processing depth. Accordingly, it is preferable to employ the first or second manufacturing method as described above.

### <Second Configuration Example of Solid-State Image Sensor>

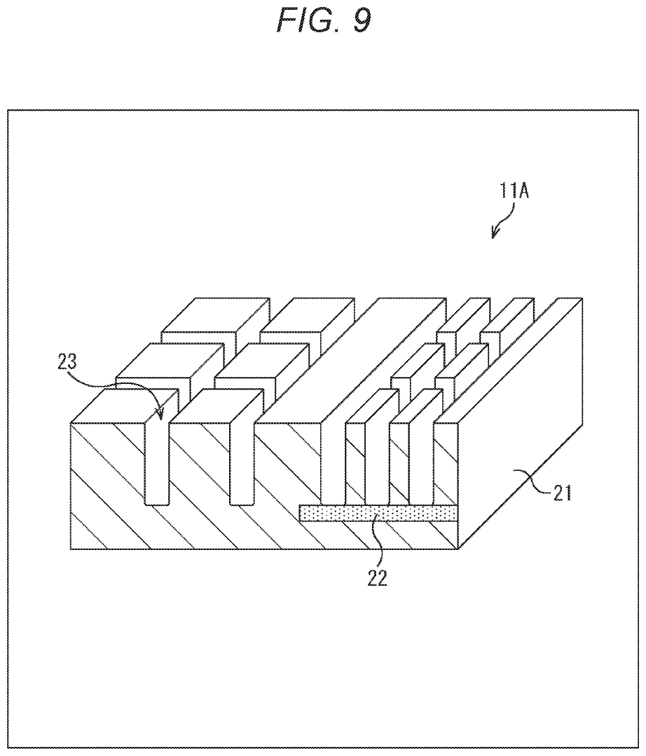

A second embodiment of the solid-state image sensor to which the present technology is applied will be described with reference to FIG. 9.

In a solid-state image sensor 11A shown in FIG. 9, multiple dug portions 23 are formed in a groove shape. The solid-state image sensor 11A can use these dug portions 23 as trenches (RDTI: reverse side deep trench Isolation) for filling an insulator at the boundary of pixels to suppress color mixing between adjacent pixels.

Accordingly, the solid-state image sensor 11A can make the insulation performance between pixels uniform for each device by using the groove-shaped dug portion 23. Hence, device characteristics can be stabilized.

### <Third Configuration Example of Solid-State Image Sensor>

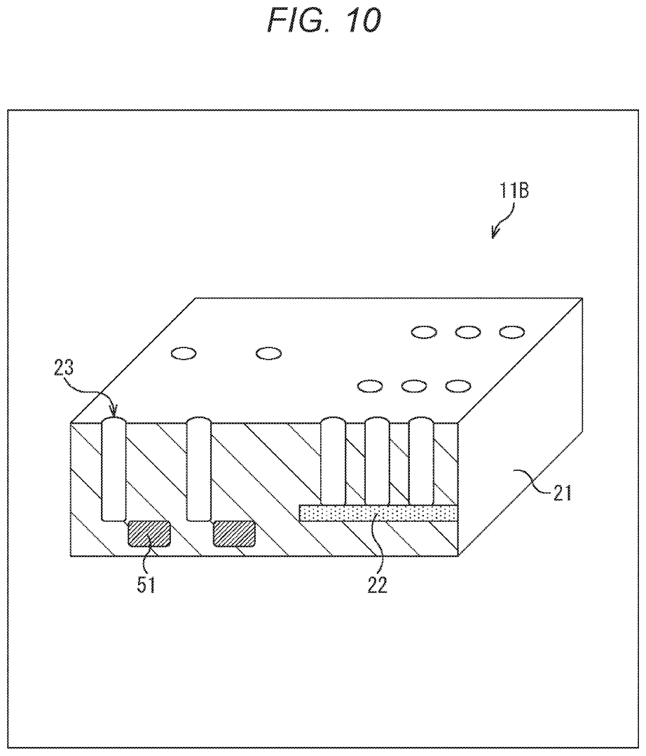

A third embodiment of the solid-state image sensor to which the present technology is applied will be described with reference to FIG. 10.

A solid-state image sensor 11B shown in FIG. 10 is a vertical spectroscopic device in which a red photodiode (PD) region for photoelectrically converting red light and a blue PD region for photoelectrically converting blue light are arranged in the vertical direction of the semiconductor substrate 21. Note that the red PD area is omitted and the blue PD region 51 is shown in FIG. 10.

For example, in a configuration in which light is irradiated from the back surface (surface facing downward in FIG. 10) of a semiconductor substrate 21, blue light is photoelectrically converted in a shallow position near the back surface. Hence, in the solid-state image sensor 11B, multiple dug portions 23 are used to form a vertical electrode for reading out electric charges from the blue PD region 51 to the surface of the semiconductor substrate 21.

Accordingly, the solid-state image sensor 11B can make the depth of the vertical electrode uniform for each device by using the dug portion 23. Hence, the device characteristic regarding readout of electric charges from the blue PD region 51 can be stabilized.

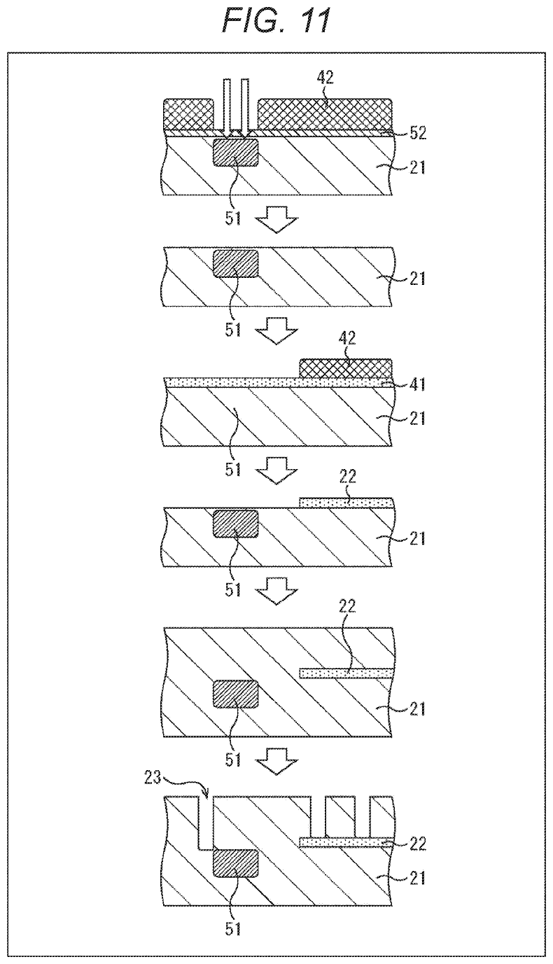

A manufacturing method of the solid-state image sensor 11B will be described with reference to FIG. 11.

In a 21st step, as shown in the first row of FIG. 11, silicon monoxide is formed on the semiconductor substrate 21 thinner than a specified thickness to form an SiO film 52 on the entire surface of the semiconductor substrate 21. Then, the blue PD region 51 is formed by disposing a resist 42 such that a region for forming the blue PD region 51 is opened, and implanting impurities near the surface of the semiconductor substrate 21 using the resist 42 as a mask.

In a 22nd step, as shown in the second row of FIG. 11, the SiO film 52 and the resist 42 are removed.

In a 23rd step, as shown in the third row of FIG. 11, a silicon nitride used as a stopper layer 22 is formed on the semiconductor substrate 21 to form an SiN film 41 on the entire surface of the semiconductor substrate 21. Then, a resist 42 is placed in accordance with the area to be the peripheral area 13.

In a 24th step, as shown in the fourth row of FIG. 11, RIE processing is performed to remove the SiN film 41 in the pixel area 12 using the resist 42, and a damaged layer on the surface of the semiconductor substrate 21 is removed. After the stopper layer 22 is formed in this manner, the resist 42 is removed. At this time, the blue PD region 51 is formed near the surface of the semiconductor substrate 21, and the stopper layer 22 is laminated on the surface of the semiconductor substrate 21. Hence, the blue PD region 51 and the stopper layer 22 are formed so as to be located near the semiconductor substrate 21 in the vertical direction.

In a 25th step, as shown in the fifth row of FIG. 11, the semiconductor substrate 21 having a specified thickness is formed by epitaxially growing silicon.

In a 26th step, as shown in the sixth row of FIG. 11, the semiconductor substrate 21 is processed to form multiple dug portions 23 using a resist, for example. At this time, as described above, by determining the end point of the etching time using the detection of the compound generated by processing the stopper layer 22, in a pixel area 12, the dug portion 23 deep enough to be near the blue PD region 51 is formed for each blue PD region 51.

With the manufacturing method described above, the processing depth of the multiple dug portions 23 formed in the pixel area 12 can be controlled accurately. As a result, it is possible to curb variation in the processing depth of the multiple dug portions 23 among the solid-state image sensors 11B, and stabilize device characteristics. Thus, the device characteristic regarding readout of electric charges from the blue PD region 51 can be stabilized.

Note that the technology of determining the end point of the etching time when etching the multiple dug portions 23 using the stopper layer 22 is not limited to the solid-state image sensor 11 alone, and can be applied to various semiconductor devices. For example, by applying the present technology to a memory and forming multiple dug portions 23 in a groove shape (see FIG. 9), the technology can be used to configure a capacitor of the memory.

That is, the present technology can be suitably applied to a device in which a semiconductor substrate 21 is deeply dug to form a dug portion 23, and which is manufactured by a process in which a semiconductor substrate 21 is added by epitaxially growing silicon. Additionally, the depth at which a stopper layer 22 is disposed can be controlled by adjusting the thickness of silicon formed by epitaxial growth.

### <Configuration Example of Electronic Device>

The solid-state image sensor 11 as described above can be applied to various electronic devices including an imaging system such as a digital still camera and a digital video camera, a mobile phone having an imaging function, and other devices having an imaging function.

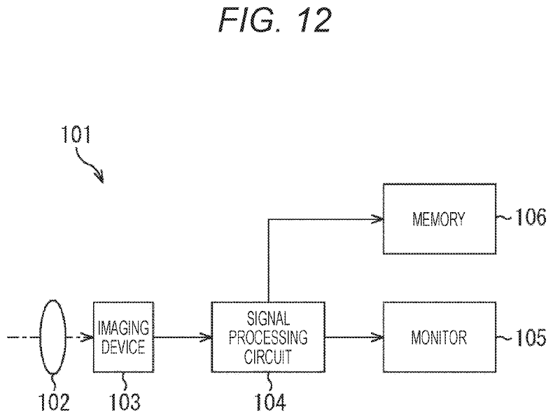

FIG. 12 is a block diagram showing a configuration example of an imager mounted on an electronic device.

As shown in FIG. 12, an imager 101 includes an optical system 102, an imaging device 103, a signal processing circuit 104, a monitor 105, and a memory 106, and can capture a still image and a moving image.

The optical system 102 includes one or more lenses, guides image light (incident light) from a subject to the imaging device 103, and forms an image on a light receiving surface (sensor unit) of the imaging device 103.

The solid-state image sensor 11 described above is applied as the imaging device 103. In the imaging device 103, electrons are accumulated for a certain period according to an image formed on the light receiving surface through the optical system 102. Then, a signal corresponding to the electrons accumulated in the imaging device 103 is supplied to the signal processing circuit 104.

The signal processing circuit 104 performs various signal processing on the pixel signals output from the imaging device 103. An image (image data) obtained by performing signal processing by the signal processing circuit 104 is supplied to the monitor 105 for display, or supplied to the memory 106 to be stored (recorded).

In the imager 101 configured as described above, by applying the above-described solid-state image sensor 11, it is possible to capture a higher-quality image in which variation in characteristics of each pixel is curbed, for example.

### <Use Example of Image Sensor>

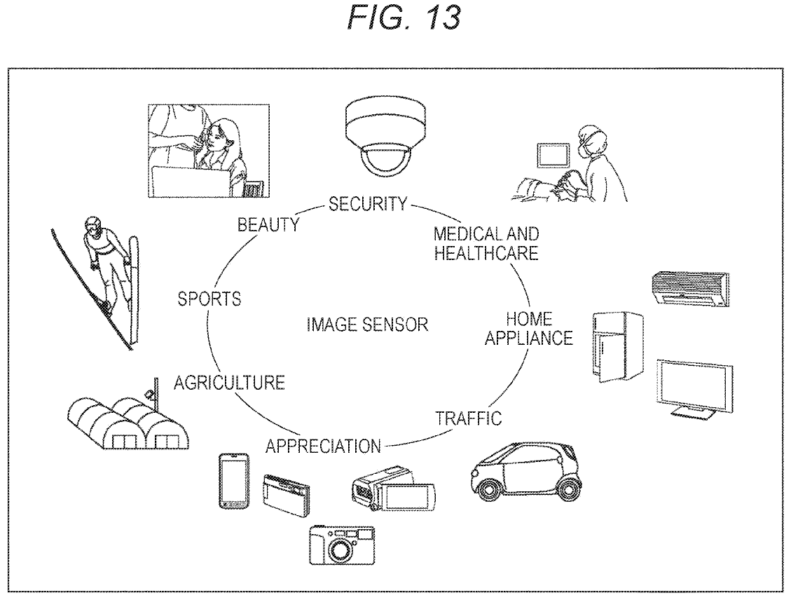

FIG. 13 is a diagram illustrating use examples of the above-described image sensor (imaging device).

The image sensor described above can be used in various cases of sensing light such as visible light, infrared light, ultraviolet light, and X-rays as described below, for example.
A device for capturing an image to be provided for appreciation, such as a digital camera or a portable device with a camera function
A device for traffic use, such as an on-vehicle sensor that captures an image of the front and back, the surroundings, the inside, or the like of a car for safe driving such as automatic stop or recognition or the like of driver's condition, a monitoring camera that monitors traveling vehicles and roads, or a distance measurement sensor that measures the distance between vehicles or the like
A device provided to a home appliance, such as a TV, a refrigerator, or an air conditioner to capture an image of a user's gesture and perform device operation according to the gesture
A device for medical and healthcare use, such as an endoscope or a device that performs blood vessel imaging by receiving infrared light
A device for security use, such as a surveillance camera for crime prevention or a camera for person authentication
A device for beauty use, such as a skin measuring instrument for capturing an image of the skin or a microscope for capturing an image of the scalp
A device for sports use, such as an action camera or a wearable camera for sports application and the like
A device for agricultural use, such as a camera for monitoring the condition of fields and crops

### <Application Example to Endoscopic Surgery System>

The technology of the present disclosure (present technology) can be applied to various products. For example, the technology of the present disclosure may be applied to an endoscopic surgery system.

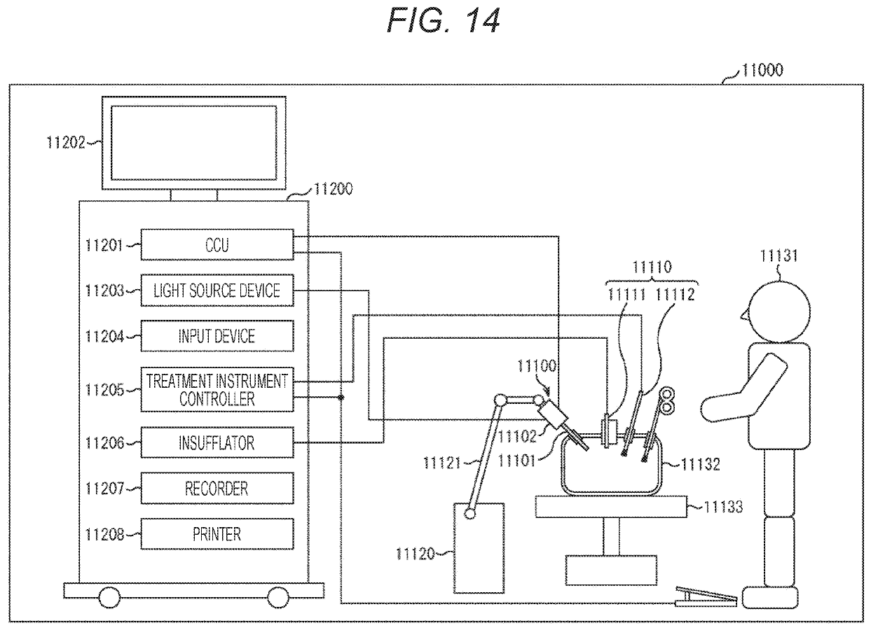

FIG. 14 is a diagram illustrating one example of a schematic configuration of an endoscopic surgery system to which the technology of the present disclosure (present technology) can be applied.

FIG. 14 shows a state in which an operator (surgeon) 11131 is performing a surgery on a patient 11132 on a patient bed 11133 using an endoscopic surgery system 11000. As shown in FIG. 14, the endoscopic surgery system 11000 includes an endoscope 11100, other surgical tools 11110 such as an insufflation tube 11111 and an energy treatment tool 11112, a support arm device 11120 that supports the endoscope 11100, and a cart 11200 on which various devices for endoscopic surgery are mounted.

The endoscope 11100 includes a lens barrel 11101 having a region of a predetermined length from the distal end inserted into the body cavity of the patient 11132, and a camera head 11102 connected to the proximal end of the lens barrel 11101. While FIG. 14 shows an example in which the endoscope 11100 is configured as a so-called rigid endoscope having a hard lens barrel 11101, the endoscope 11100 may be configured as a so-called flexible endoscope having a soft lens barrel.

An opening into which an objective lens is fitted is provided at the tip end of the lens barrel 11101. A light source device 11203 is connected to the endoscope 11100, and light generated by the light source device 11203 is guided to the tip end of the lens barrel by a light guide extending inside the lens barrel 11101. The light is radiated toward the observation target in the body cavity of the patient 11132 through the objective lens. Note that the endoscope 11100 may be a forward-viewing endoscope, an oblique-viewing endoscope, or a side-viewing endoscope.

An optical system and an imaging device are provided inside the camera head 11102, and reflected light (observation light) from an observation target is focused on the imaging device by the optical system. Observation light is photoelectrically converted by the imaging device, and an electrical signal corresponding to the observation light, that is, an image signal corresponding to the observed image is generated. The image signal is transmitted to a camera control unit (CCU) 11201 as RAW data.

The CCU 11201 includes a central processing unit (CPU), a graphics processing unit (GPU), and the like, and performs centralized control of operations of the endoscope 11100 and a display device 11202. Further, the CCU 11201 receives an image signal from the camera head 11102, and performs various image processing on the image signal for displaying an image based on the image signal, such as development processing (demosaicing processing).

The display device 11202 displays an image based on the image signal subjected to image processing by the CCU 11201 under the control of the CCU 11201.

The light source device 11203 includes a light source such as a light emitting diode (LED), for example, and supplies irradiation light for imaging a surgical site or the like to the endoscope 11100.

An input device 11204 is an input interface for the endoscopic surgery system 11000. The user can input various information and instructions to the endoscopic surgery system 11000 through the input device 11204. For example, the user inputs an instruction or the like to change imaging conditions (type of irradiation light, magnification, focal length, and the like) by the endoscope 11100.

A treatment instrument controller 11205 controls the operation of the energy treatment tool 11112 for tissue ablation, incision, blood vessel sealing, or the like. In order to inflate the body cavity of the patient 11132 for the purpose of securing the visual field by the endoscope 11100 and securing the operator's work space, an insufflator 11206 is used send gas into the body cavity through the insufflation tube 11111. A recorder 11207 is a device capable of recording various information related to surgery. A printer 11208 is a device that can print various information related to surgery in various formats such as text, images, or graphs.

Note that the light source device 11203 that supplies irradiation light when imaging the surgical site to the endoscope 11100 can include a white light source configured by an LED, a laser light source, or a combination thereof, for example. In a case where a white light source is configured by a combination of RGB laser light sources, the output intensity and output timing of each color (each wavelength) can be controlled with high accuracy. Hence, white balance of the captured image can be adjusted in the light source device 11203. Additionally, in this case, it is also possible to capture images corresponding to RGB in a time-sharing manner, by irradiating the laser light from each of the RGB laser light sources onto the observation target in a time-sharing manner, and controlling the operation of the imaging device of the camera head 11102 in synchronization with the irradiation timing. According to this method, a color image can be obtained without providing a color filter in the imaging device.

Additionally, the operation of the light source device 11203 may be controlled so as to change the intensity of light to be output every predetermined time. By acquiring images in a time-sharing manner by controlling the operation of the imaging device of the camera head 11102 in synchronization with the timing of the change in the intensity of light and synthesizing the images, a wide-dynamic range image without so-called blackout and overexposure can be generated.

Additionally, the light source device 11203 may be capable of supplying light in a predetermined wavelength band corresponding to special light observation. In special light observation, so-called narrow band imaging is performed in which a predetermined tissue such as a blood vessel on the surface of the mucosa is imaged with high contrast, by utilizing the wavelength dependence of light absorption in body tissue and irradiating light in a narrower band compared to irradiation light during normal observation (i.e., white light), for example. Alternatively, in special light observation, fluorescence observation may be performed in which an image is obtained by fluorescence generated by irradiating excitation light. In fluorescence observation, it is possible to irradiate the body tissue with excitation light and observe fluorescence from the body tissue (autofluorescence observation), or locally inject a reagent such as indocyanine green (ICG) into the body tissue and irradiate the body tissue with excitation light corresponding to the fluorescence wavelength of the reagent to obtain a fluorescence image, for example. The light source device 11203 may be capable of supplying narrowband light and/or excitation light corresponding to such special light observation.

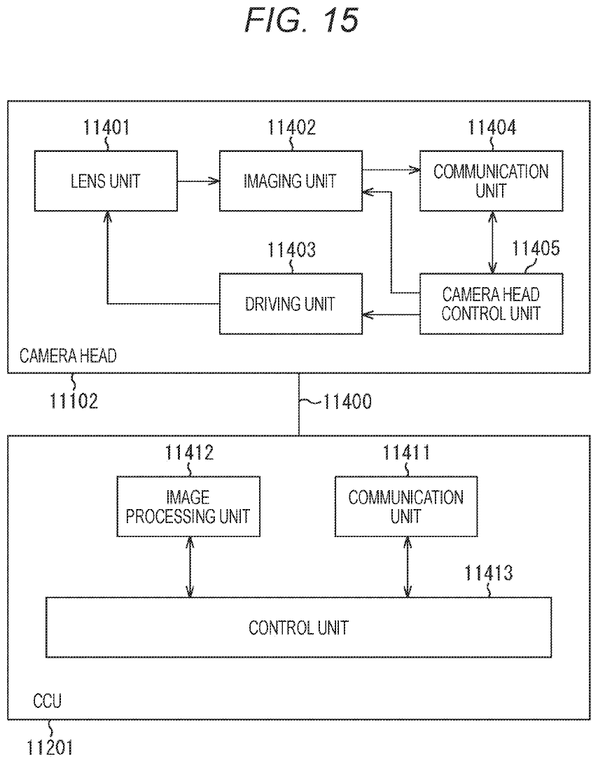

FIG. 15 is a block diagram showing one example of a functional configuration of the camera head 11102 and the CCU 11201 shown in FIG. 14.

The camera head 11102 includes a lens unit 11401, an imaging unit 11402, a driving unit 11403, a communication unit 11404, and a camera head control unit 11405. The CCU 11201 has a communication unit 11411, an image processing unit 11412, and a control unit 11413. The camera head 11102 and the CCU 11201 are communicably connected to each other by a transmission cable 11400.

The lens unit 11401 is an optical system provided at a connection portion with the lens barrel 11101. Observation light taken in from the tip end of the lens barrel 11101 is guided to the camera head 11102 and enters the lens unit 11401. The lens unit 11401 is configured by combining multiple lenses including a zoom lens and a focus lens.

The imaging device included in the imaging unit 11402 may be one (so-called single plate type) or plural (so-called multi-plate type). In the case where the imaging unit 11402 is configured as a multi-plate type, image signals corresponding to RGB may be generated by each imaging device, and a color image may be obtained by synthesizing the image signals, for example. Alternatively, the imaging unit 11402 may be configured to include a pair of imaging devices for respectively acquiring right-eye and left-eye image signals corresponding to three-dimensional (3D) display. By performing the 3D display, the operator 11131 can more accurately grasp the depth of the living tissue in the surgical site. Note that in the case where the imaging unit 11402 is configured as a multi-plate type, multiple lens units 11401 can be provided corresponding to the imaging devices.

Additionally, the imaging unit 11402 does not necessarily have to be provided in the camera head 11102. For example, the imaging unit 11402 may be provided inside the lens barrel 11101 immediately after the objective lens.

The driving unit 11403 includes an actuator, and moves the zoom lens and the focus lens of the lens unit 11401 by a predetermined distance along the optical axis under the control of the camera head control unit 11405. With this configuration, the magnification and focus of the image captured by the imaging unit 11402 can be adjusted as appropriate.

The communication unit 11404 includes a communication device for exchanging various information with the CCU 11201. The communication unit 11404 transmits the image signal obtained from the imaging unit 11402 as RAW data to the CCU 11201 through the transmission cable 11400.

Additionally, the communication unit 11404 receives a control signal for controlling the operation of the camera head 11102 from the CCU 11201 and supplies the control signal to the camera head control unit 11405. For example, the control signal includes information regarding imaging conditions such as information that specifies the frame rate of the captured image, information that specifies the exposure value at the time of imaging, and/or information that specifies the magnification and focus of the captured image.

Note that the imaging conditions such as the frame rate, exposure value, magnification, and focus described above may be appropriately specified by the user, or may be automatically set by the control unit 11413 of the CCU 11201 on the basis of the acquired image signal. In the latter case, the so-called auto exposure (AE) function, auto focus (AF) function, and auto white balance (AWB) function are installed in the endoscope 11100.

The camera head control unit 11405 controls the operation of the camera head 11102 on the basis of a control signal from the CCU 11201 received through the communication unit 11404.

The communication unit 11411 includes a communication device for exchanging various information with the camera head 11102. The communication unit 11411 receives an image signal transmitted from the camera head 11102 through the transmission cable 11400.

The communication unit 11411 transmits a control signal for controlling the operation of the camera head 11102 to the camera head 11102. The image signal and the control signal can be transmitted by electrical communication, optical communication, or the like.

The image processing unit 11412 performs various image processing on the image signal that is RAW data transmitted from the camera head 11102.

The control unit 11413 performs various control related to imaging of the surgical site or the like by the endoscope 11100 and display of a captured image obtained by imaging of the surgical site or the like. For example, the control unit 11413 generates a control signal for controlling the operation of the camera head 11102.

Additionally, the control unit 11413 causes the display device 11202 to display a captured image of a surgical site or the like on the basis of the image signal subjected to image processing by the image processing unit 11412. At this time, the control unit 11413 may recognize various objects in the captured image using various image recognition technologies. For example, the control unit 11413 can recognize surgical tools such as forceps, specific biological parts, bleeding, mist when using the energy treatment tool 11112, and the like by detecting the shape, color, and the like of the edge of the object included in the captured image. When displaying the captured image on the display device 11202, the control unit 11413 may superimpose and display various surgery support information on the image of the surgical site using the recognition result. Surgery support information is displayed in a superimposed manner and presented to the operator 11131, thereby reducing the burden on the operator 11131 and allowing the operator 11131 to proceed with surgery reliably.

The transmission cable 11400 that connects the camera head 11102 and the CCU 11201 is an electric signal cable provided for electric signal communication, an optical fiber provided for optical communication, or a composite cable thereof.

Here, while communication is performed by wire using the transmission cable 11400 in the example shown in FIG. 15, communication between the camera head 11102 and the CCU 11201 may be performed wirelessly.

One example of the endoscopic surgery system to which the technology of the present disclosure can be applied has been described above. The technology of the present disclosure can be applied to the endoscope 11100, the camera head 11102 (imaging unit 11402 thereof), and the like, among the configurations described above. With this configuration, multiple dug portions 23 can be processed so as to have a constant processing depth for each device, and variation in characteristic among devices can be avoided. As a result, a constant quality can be ensured.

Note that while an endoscopic surgery system has been described herein as one example, the technology of the present disclosure may be applied to a microscope surgery system and the like, for example.

### <Example of Application to Movable Body>

The technology of the present disclosure (present technology) can be applied to various products. For example, the technology of the present disclosure may be implemented as a device mounted on any of movable bodies including a car, an electric car, a hybrid electric car, a motorcycle, a bicycle, personal mobility, an airplane, a drone, a ship, a robot, and the like.

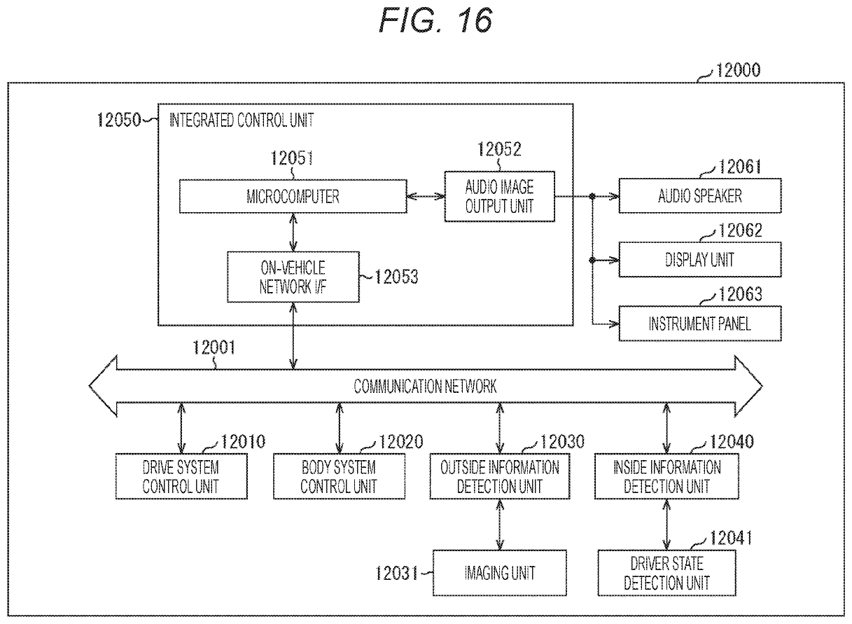

FIG. 16 is a block diagram showing a schematic configuration example of a vehicle control system which is one example of a movable body control system to which the technology of the present disclosure can be applied.

A vehicle control system 12000 includes multiple electronic control units connected through a communication network 12001. In the example shown in FIG. 16, the vehicle control system 12000 includes a drive system control unit 12010, a body system control unit 12020, an outside information detection unit 12030, an inside information detection unit 12040, and an integrated control unit 12050. Additionally, as a functional configuration of the integrated control unit 12050, a microcomputer 12051, an audio image output unit 12052, and an on-vehicle network interface (I/F) 12053 are illustrated.

The drive system control unit 12010 controls the operation of devices related to a drive system of the vehicle according to various programs. For example, the drive system control unit 12010 functions as a control device of a drive force generation device for generating a drive force of a vehicle such as an internal combustion engine or a drive motor, a drive force transmission mechanism for transmitting the drive force to wheels, a steering mechanism that adjusts the steering angle of the vehicle, a braking device that generates a braking force of the vehicle, and the like.

The body system control unit 12020 controls the operation of various devices equipped on the vehicle body according to various programs. For example, the body system control unit 12020 functions as a controller of a keyless entry system, a smart key system, a power window device, or a controller of various lamps such as a headlamp, a back lamp, a brake lamp, a blinker, or a fog lamp. In this case, the body system control unit 12020 may receive input of radio waves transmitted from a portable device substituting a key or signals of various switches. The body system control unit 12020 receives input of the radio wave or signals and controls the door lock device, the power window device, the lamp, or the like of the vehicle.

The outside information detection unit 12030 detects information outside the vehicle on which the vehicle control system 12000 is mounted. For example, an imaging unit 12031 is connected to the outside information detection unit 12030. The outside information detection unit 12030 causes the imaging unit 12031 to capture an image of the outside of the vehicle, and receives the captured image. The outside information detection unit 12030 may perform object detection processing or distance detection processing of a person, a vehicle, an obstacle, a sign, characters on a road surface, or the like on the basis of the received image.

The imaging unit 12031 is an optical sensor that receives light and outputs an electrical signal according to the amount of light received. The imaging unit 12031 can output an electric signal as an image or can output the electrical signal as distance measurement information. Further, the light received by the imaging unit 12031 may be visible light or non-visible light such as infrared light.

The inside information detection unit 12040 detects information regarding the inside of the vehicle. For example, a driver state detection unit 12041 that detects a state of a driver is connected to the inside information detection unit 12040. The driver state detection unit 12041 includes, for example, a camera for capturing an image of the driver, and the inside information detection unit 12040 may calculate the degree of fatigue or concentration of the driver or may determine whether the driver is asleep, on the basis of detection information input from the driver state detection unit 12041.

The microcomputer 12051 can calculate a control target value of the drive force generation device, the steering mechanism, or the braking device on the basis of information regarding the inside or outside of the vehicle acquired by the outside information detection unit 12030 or the inside information detection unit 12040, and output a control instruction to the drive system control unit 12010. For example, the microcomputer 12051 can perform coordinated control aimed to achieve the functions of an advanced driver assistance system (ADAS) including collision avoidance or shock mitigation of a vehicle, follow-up traveling based on the inter-vehicle distance, constant-speed traveling, vehicle collision warning, vehicle lane departure warning, or the like.

Additionally, the microcomputer 12051 can control the drive force generation device, the steering mechanism, the braking device, and the like on the basis of information regarding the periphery of the vehicle acquired by the outside information detection unit 12030 or the inside information detection unit 12040, and thereby perform coordinated control aimed for automatic driving, for example, of traveling autonomously without depending on the driver's operation.

Further, the microcomputer 12051 can output a control command to the body system control unit 12030 on the basis of the information regarding the outside of the vehicle acquired by the outside information detection unit 12030. For example, the microcomputer 12051 can control the headlamp according to the position of the preceding vehicle or oncoming vehicle detected by the outside information detection unit 12030, and perform cooperative control aimed for glare prevention such as switching from high beam to low beam.

The audio image output unit 12052 transmits an output signal of at least one of audio or image to an output device capable of visually or aurally notifying a passenger or the outside of a vehicle of information. In the example of FIG. 16, an audio speaker 12061, a display unit 12062, and an instrument panel 12063 are illustrated as the output device. The display unit 12062 may include at least one of an onboard display or a head-up display, for example.

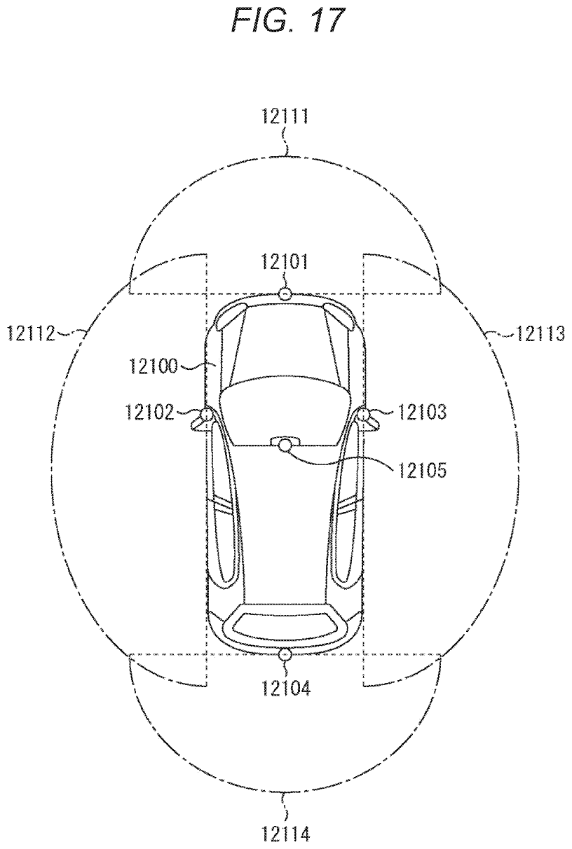

FIG. 17 is a diagram showing an example of an installation position of the imaging unit 12031.

In FIG. 17, imaging units 12101, 12102, 12103, 12104, and 12105 are included as the imaging unit 12031.

For example, the imaging units 12101, 12102, 12103, 12104, and 12105 are provided in positions such as a front nose, a side mirror, a rear bumper, a back door, and an upper portion of a windshield in a vehicle compartment of the vehicle 12100. The imaging unit 12101 provided on the front nose and the imaging unit 12105 provided on the upper portion of the windshield in the vehicle compartment mainly acquire images of the front of the vehicle 12100. The imaging units 12102 and 12103 provided on the side mirrors mainly acquire images of the side of the vehicle 12100. The imaging unit 12104 provided on the rear bumper or the back door mainly acquires an image of the rear of the vehicle 12100. The imaging unit 12105 provided on the upper portion of the windshield in the vehicle compartment is mainly used to detect a preceding vehicle or a pedestrian, an obstacle, a traffic light, a traffic sign, a lane, or the like.

Note that FIG. 17 shows one example of the imaging range of the imaging units 12101 to 12104. An imaging range 12111 indicates the imaging range of the imaging unit 12101 provided on the front nose, imaging ranges 12112 and 12113 indicate the imaging ranges of the imaging units 12102 and 12103 respectively provided on the side mirrors, and an imaging range 12114 indicates the imaging range of the imaging unit 12104 provided on the rear bumper or the back door. For example, by superimposing the pieces of image data captured by the imaging units 12101 to 12104 on one another, a bird's eye view of the vehicle 12100 viewed from above can be obtained.

At least one of the imaging units 12101 to 12104 may have a function of acquiring distance information. For example, at least one of the imaging units 12101 to 12104 may be a stereo camera including multiple imaging devices, or may be an imaging device having pixels for phase difference detection.

For example, the microcomputer 12051 can obtain the distance to each three-dimensional object in the imaging ranges 12111 to 12114 and the temporal change of this distance (relative velocity with respect to vehicle 12100) on the basis of distance information obtained from the imaging units 12101 to 12104, to extract, in particular, the closest three-dimensional object on the traveling path of the vehicle 12100 traveling at a predetermined speed (e.g., 0 km/h or more) in substantially the same direction as the vehicle 12100, as the preceding vehicle. Moreover, the microcomputer 12051 can set an inter-vehicle distance to be secured in advance before the preceding vehicle, and perform automatic brake control (including follow-up stop control), automatic acceleration control (including follow-up start control), and the like. As described above, it is possible to perform coordinated control aimed for automatic driving, for example, of traveling autonomously without depending on the driver's operation.

For example, the microcomputer 12051 can extract while classifying three-dimensional object data related to three-dimensional objects into two-wheeled vehicles, ordinary vehicles, large vehicles, pedestrians, and other three-dimensional objects such as telephone poles on the basis of distance information obtained from the imaging units 12101 to 12104, and use the data for automatic avoidance of obstacles. For example, the microcomputer 12051 identifies obstacles around the vehicle 12100 into obstacles visible and obstacles hardly visible to the driver of the vehicle 12100. Then, the microcomputer 12051 determines the collision risk indicating the degree of risk of collision with each obstacle, and when the collision risk is a set value or more and there is a possibility of a collision, the microcomputer 12051 can perform driving support for avoiding collision by outputting a warning to the driver through the audio speaker 12061 or the display unit 12062, or performing forcible deceleration or steering for avoidance through the drive system control unit 12010.

At least one of the imaging units 12101 to 12104 may be an infrared camera that detects infrared light. For example, the microcomputer 12051 can recognize a pedestrian by determining whether or not a pedestrian is present in the images captured by the imaging units 12101 to 12104. Such pedestrian recognition is performed by a procedure of extracting feature points in images captured by the imaging units 12101 to 12104 as infrared cameras, and a procedure of performing pattern matching processing on a series of feature points indicating the outline of an object to determine whether or not the object is a pedestrian, for example. If the microcomputer 12051 determines that a pedestrian is present in the images captured by the imaging units 12101 to 12104 and recognizes the pedestrian, the audio image output unit 12052 controls the display unit 12062 to superimpose a square outline for emphasis on the recognized pedestrian. Additionally, the audio image output unit 12052 may control the display unit 12062 to display an icon or the like indicating a pedestrian in a desired position.

The example of the vehicle control system to which the technology of the present disclosure can be applied has been described above. The technology of the present disclosure is applicable to the imaging unit 12031 or the like among the configurations described above. With this configuration, multiple dug portions 23 can be processed so as to have a constant processing depth for each device, and variation in characteristic among devices can be avoided. As a result, a constant quality can be ensured.

### <Example of Combination of Configuration>

Note that the present technology can also be configured in the following manner.

(1)

A semiconductor device including:

an effective region that is a region where a semiconductor element required to function effectively is formed on a semiconductor substrate;

an ineffective region that is a region in the semiconductor substrate where the semiconductor element is not formed;

a stopper layer that is formed in the semiconductor substrate at a predetermined depth in the ineffective region and includes a material different from the semiconductor substrate; and

a dug portion formed by digging the effective region and the ineffective region of the semiconductor substrate to a depth corresponding to the stopper layer.

(2)

The semiconductor device described in the above (1), in which

an end point of a processing time for digging the dug portion is determined by using detection of a compound containing a material of the stopper layer.

(3)

The semiconductor device described in the above (1) or (2), in which

the stopper layer can be formed on a scribe line including a dicing width.

(4)

The semiconductor device described in any one of the above (1) to (3), in which

the semiconductor device is manufactured by forming the stopper layer on the semiconductor substrate thinner than a specified thickness, and then epitaxially growing the semiconductor substrate to a specified thickness.

(5)

The semiconductor device described in the above (4), in which

the stopper layer is formed by depositing a material on the semiconductor substrate thinner than a specified thickness, and removing a film formed on the entire surface of the semiconductor substrate from the effective region.

(6)

The semiconductor device described in the above (4), in which

the stopper layer is formed by implanting an impurity near the surface of the semiconductor substrate in the ineffective region.

(7)

The semiconductor device described in any one of the above (1) to (6), in which

the dug portion is formed in a circular blind hole shape.

(8)

The semiconductor device described in any one of the above (1) to (6), in which

the dug portion is formed in a groove shape.

(9)

A solid-state image sensor including:

a pixel region that is a region where a pixel required to function effectively is formed on a semiconductor substrate;

a peripheral region that is a region in the semiconductor substrate where the pixel is not formed;

a stopper layer that is formed in the semiconductor substrate at a predetermined depth in the peripheral region and includes a material different from the semiconductor substrate; and

a dug portion formed by digging the pixel region and the peripheral region of the semiconductor substrate to a depth corresponding to the stopper layer.

(10)

The solid-state image sensor described in the above (9), in which

the dug portion is used to form a vertical electrode for reading out electric charges from a photodiode formed in the semiconductor substrate at a predetermined depth.

(11)

A manufacturing method of a semiconductor device that includes:

an effective region that is a region where a semiconductor element required to function effectively is formed on a semiconductor substrate;

an ineffective region that is a region in the semiconductor substrate where the semiconductor element is not formed;

a stopper layer that is formed in the semiconductor substrate at a predetermined depth in the ineffective region and includes a material different from the semiconductor substrate; and

a dug portion formed by digging the effective region and the ineffective region of the semiconductor substrate to a depth corresponding to the stopper layer, the method including:

forming the stopper layer on the semiconductor substrate thinner than a specified thickness; and

epitaxially growing the semiconductor substrate to a specified thickness.

(12)

An electronic device including a semiconductor device that has:

an effective region that is a region where a semiconductor element required to function effectively is formed on a semiconductor substrate;

an ineffective region that is a region in the semiconductor substrate where the semiconductor element is not formed;

a stopper layer that is formed in the semiconductor substrate at a predetermined depth in the ineffective region and includes a material different from the semiconductor substrate; and

a dug portion formed by digging the effective region and the ineffective region of the semiconductor substrate to a depth corresponding to the stopper layer.

Note that the embodiments are not limited to the above-described embodiments, and various modifications can be made without departing from the scope of the present disclosure. Additionally, the effect described in the present specification is merely an illustration and is not restrictive. Hence, other effects can be obtained.

### REFERENCE SIGNS LIST

11 Solid-state image sensor
12 Pixel area
13 Peripheral area
21 Semiconductor substrate
22 Stopper layer
23 Dug portion
31 Dicing region
41 SiN film
42 Resist
51 Blue PD region
52 SiO film

1. A semiconductor device comprising:
an effective region that is a region where a semiconductor element required to function effectively is formed on a semiconductor substrate;
an ineffective region that is a region in the semiconductor substrate where the semiconductor element is not formed;
a stopper layer that is formed in the semiconductor substrate at a predetermined depth in the ineffective region and includes a material different from the semiconductor substrate; and
a dug portion formed by digging the effective region and the ineffective region of the semiconductor substrate to a depth corresponding to the stopper layer.

2. The semiconductor device according to claim 1, wherein
an end point of a processing time for digging the dug portion is determined by using detection of a compound containing a material of the stopper layer.

3. The semiconductor device according to claim 1, wherein
the stopper layer can be formed on a scribe line including a dicing width.

4. The semiconductor device according to claim 1, wherein
the semiconductor device is manufactured by forming the stopper layer on the semiconductor substrate thinner than a specified thickness, and then epitaxially growing the semiconductor substrate to a specified thickness.

5. The semiconductor device according to claim 4, wherein
the stopper layer is formed by depositing a material on the semiconductor substrate thinner than a specified thickness, and removing a film formed on the entire surface of the semiconductor substrate from the effective region.

6. The semiconductor device according to claim 4, wherein
the stopper layer is formed by implanting an impurity near the surface of the semiconductor substrate in the ineffective region.

7. The semiconductor device according to claim 1, wherein
the dug portion is formed in a circular blind hole shape.

8. The semiconductor device according to claim 1, wherein
the dug portion is formed in a groove shape.

9. A solid-state image sensor comprising:
a pixel region that is a region where a pixel required to function effectively is formed on a semiconductor substrate;
a peripheral region that is a region in the semiconductor substrate where the pixel is not formed;
a stopper layer that is formed in the semiconductor substrate at a predetermined depth in the peripheral region and includes a material different from the semiconductor substrate; and
a dug portion formed by digging the pixel region and the peripheral region of the semiconductor substrate to a depth corresponding to the stopper layer.

10. The solid-state image sensor according to claim 9, wherein
the dug portion is used to form a vertical electrode for reading out electric charges from a photodiode formed in the semiconductor substrate at a predetermined depth.

11. A manufacturing method of a semiconductor device that includes:
an effective region that is a region where a semiconductor element required to function effectively is formed on a semiconductor substrate;
an ineffective region that is a region in the semiconductor substrate where the semiconductor element is not formed;
a stopper layer that is formed in the semiconductor substrate at a predetermined depth in the ineffective region and includes a material different from the semiconductor substrate; and
a dug portion formed by digging the effective region and the ineffective region of the semiconductor substrate to a depth corresponding to the stopper layer, the method comprising:
forming the stopper layer on the semiconductor substrate thinner than a specified thickness; and
epitaxially growing the semiconductor substrate to a specified thickness.

12. An electronic device comprising a semiconductor device that has:
an effective region that is a region where a semiconductor element required to function effectively is formed on a semiconductor substrate;
an ineffective region that is a region in the semiconductor substrate where the semiconductor element is not formed;
a stopper layer that is formed in the semiconductor substrate at a predetermined depth in the ineffective region and includes a material different from the semiconductor substrate; and
a dug portion formed by digging the effective region and the ineffective region of the semiconductor substrate to a depth corresponding to the stopper layer.
